(19) United States
(12) Patent Application Publication
(10) Pub. No.: US 2013/0328071 A1
(43) Pub. Date: Dec. 12, 2013

(54) MULTILAYER FILM SUBSTRATE, METHOD OF MANUFACTURING MULTILAYER FILM SUBSTRATE, METHOD OF MANUFACTURING SEMICONDUCTOR DEVICE, METHOD OF MANUFACTURING DISPLAY UNIT, AND METHOD OF MANUFACTURING ELECTRONIC APPARATUS

(71) Applicant: Sony Corporation, Tokyo (JP)

(72) Inventor: Masanobu Tanaka, Kanagawa (JP)

(73) Assignee: Sony Corporation, Tokyo (JP)

(21) Appl. No.: 13/909,632

(22) Filed: Jun. 4, 2013

(30) Foreign Application Priority Data
Jun. 12, 2012 (JP) 2012-132947

(51) Int. Cl. H01L 27/12

(52) U.S. Cl. CPC H01L 27/1259; H01L 27/1214
USPC 257/88; 438/34

(57) ABSTRACT

A method of manufacturing a multilayer film substrate, the method includes: forming an adhesion control layer on a first substrate, the adhesion control layer including an adhesion section and a separation section; forming a to-be-peeled layer being fixed to the first substrate in the adhesion section and being inhibited from being adhered to the first substrate in the separation section; laminating a function layer on the to-be-peeled layer; peeling the function layer off from the first substrate together with the to-be-peeled layer; and providing the function layer on a second substrate.

### BACKGROUND

The present technology relates to a multilayer film substrate having a function layer such as a semiconductor film and a display layer and to a method of manufacturing the same. The present technology also relates to a method of manufacturing a semiconductor device, a method of manufacturing a display unit, and a method of manufacturing an electronic apparatus that use the method of manufacturing the multilayer film substrate.

In a display unit such as a flexible display, first, a flexible substrate (second substrate) is fixed on a substrate (first substrate) such as glass, and a function layer such as a TFT (Thin Film Transistor) layer and a display layer is formed on the first substrate. After the function layer is formed on the first substrate, the second substrate is peeled off from the first substrate, and accordingly, the flexible display is completed.

However, in the foregoing method, there is a disadvantage that heat is generated at the time of forming the function layer, and the second substrate made of a resin material or the like is melted by the heat. Further, since the heat elongates and contracts the second substrate, precise position adjustment of respective sections of the function layer is difficult. Further, there is a disadvantage that an adhesive for fixing the second substrate on the first substrate is hardened by heat, and the second substrate is peeled off from the first substrate in the middle of manufacture.

To address the foregoing disadvantages, the following method has been proposed (for example, Japanese Unexamined Patent Application Publication No. 2011-142332 (JP2011-142332A)). In such a method, after a function layer is formed on a first substrate, the function layer is peeled off from the first substrate and is moved onto a second layer. In JP2011-142332A, the following method is described. In such a method, a metal layer is provided on the first substrate, an oxidation layer and the function layer are laminated in this order on the metal layer, and subsequently, the metal layer is irradiated with a laser. In this method, a brittle metallic oxide layer is formed by laser irradiation, and therefore, the function layer is allowed to be easily peeled off from the first substrate.

### SUMMARY

However, in the method of JP2011-142332, since the laser irradiation is performed after the function layer is formed on the first substrate, the function layer may be degraded by heat generated by the laser irradiation.

It is desirable to provide a multilayer film substrate in which degradation of a function layer is suppressed and a method of manufacturing the same. It is also desirable to provide a method of manufacturing a semiconductor device, a method of manufacturing a display unit, and a method of manufacturing an electronic apparatus that use the method of manufacturing the multilayer film substrate.

According to an embodiment of the present technology, there is provided a method of manufacturing a multilayer film substrate, the method including: forming an adhesion control layer on a first substrate, the adhesion control layer including an adhesion section and a separation section; forming a to-be-peeled layer being fixed to the first substrate in the adhesion section and being inhibited from being adhered to the first substrate in the separation section; laminating a function layer on the to-be-peeled layer; peeling the function layer off from the first substrate together with the to-be-peeled layer; and providing the function layer on a second substrate.

According to an embodiment of the present technology, there is provided a method of manufacturing a semiconductor device, the method including: forming an adhesion control layer on a first substrate, the adhesion control layer including an adhesion section and a separation section; forming a to-be-peeled layer being fixed to the first substrate in the adhesion section and being inhibited from being adhered to the first substrate in the separation section; laminating a semiconductor film on the to-be-peeled layer; peeling the semiconductor film off from the first substrate together with the to-be-peeled layer; and providing the semiconductor film on a second substrate.

According to an embodiment of the present technology, there is provided a method of manufacturing a display unit, the method comprising: forming an adhesion control layer on a first substrate, the adhesion control layer including an adhesion section and a separation section; forming a to-be-peeled layer being fixed to the first substrate in the adhesion section and being inhibited from being adhered to the first substrate in the separation section; laminating a display layer on the to-be-peeled layer; peeling the display layer off from the first substrate together with the to-be-peeled layer; and providing the display layer on a second substrate.

According to an embodiment of the present technology, there is provided a method of manufacturing an electronic apparatus, the method including forming a display unit, the forming the display unit including: forming an adhesion control layer on a first substrate, the adhesion control layer including an adhesion section and a separation section; forming an to-be-peeled layer being fixed to the first substrate in the adhesion section and being inhibited from being adhered to the first substrate in the separation section; laminating a display layer on the to-be-peeled layer; peeling the display layer off from the first substrate together with the to-be-peeled layer; and providing the display layer on a second substrate.

In the method of manufacturing the multilayer film substrate, the method of manufacturing the semiconductor device, the method of manufacturing the display unit, and the method of manufacturing the electronic apparatus according to the embodiments of the present technology, the adhesion section and the separation section are provided in the adhesion control layer in advance. Therefore, the function layer provided on the first substrate is moved onto the second substrate without performing a treatment such as laser irradiation.

According to an embodiment of the present technology, there is provided a multilayer film substrate including: on a substrate, a to-be-peeled layer including a concave section on a rear surface thereof; and a function layer laminated on the to-be-peeled layer.

In the multilayer film substrate according to the embodiment of the present technology, due to the concave section of the to-be-peeled layer, adhesiveness in the concave section is allowed to be different from adhesiveness in a section (convex section) other than the concave section. Specifically, even in the case where the to-be-peeled layer and the function layer are formed on another substrate (first substrate), adhesiveness with respect to the first substrate is allowed to be changed by the concave section of the to-be-peeled layer. Therefore, the to-be-peeled layer and the function layer are separated from the first substrate without performing a treatment such as laser irradiation.

According to the method of manufacturing the multilayer film substrate, the method of manufacturing the semiconductor device, the method of manufacturing the display unit, and the method of manufacturing the electronic apparatus of the embodiments of the present technology, the adhesion section and the separation section are provided in the adhesion control layer. According to the multilayer film substrate of the embodiment of the present technology, the concave section is provided on the rear surface of the to-be-peeled layer. Therefore, the function layer is allowed to be moved from the first substrate to the second substrate without degrading the function layer by a treatment such as laser irradiation.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a cross-sectional view illustrating a configuration of a display unit according to a first embodiment of the present technology.

FIG. 2 is a diagram illustrating a whole configuration of the display unit illustrated in FIG. 1.

FIG. 3 is a diagram illustrating an example of a pixel drive circuit illustrated in FIG. 2.

FIG. 4 is a cross-sectional view illustrating configurations of a TFT layer and a display layer illustrated in FIG. 1.

FIG. 5A is a cross-sectional view illustrating a method of manufacturing the display unit illustrated in FIG. 1.

FIG. 5B is a cross-sectional view illustrating a step following a step of FIG. 5A.

FIG. 5C is a cross-sectional view illustrating a step following the step of FIG. 5B.

FIG. 6 is a plan view illustrating the step of FIG. 5B.

FIG. 7A is a cross-sectional view illustrating a step following the step of FIG. 5C.

FIG. 7B is a cross-sectional view illustrating a step following the step of FIG. 7A.

FIG. 7C is a cross-sectional view illustrating a step following the step of FIG. 7B.

FIG. 8A is a cross-sectional view illustrating a step following the step of FIG. 7C.

FIG. 8B is a cross-sectional view illustrating a step following the step of FIG. 8A.

FIG. 9A is a cross-sectional view illustrating a method of manufacturing a display unit according to a comparative example.

FIG. 9B is a cross-sectional view illustrating a step following a step of FIG. 9A.

FIG. 10A is a cross-sectional view illustrating a step following the step of FIG. 9B.

FIG. 10B is a cross-sectional view illustrating a step following the step of FIG. 10A.

FIG. 11A is a cross-sectional view illustrating a method of manufacturing a display unit according to Modification 1.

FIG. 11B is a cross-sectional view illustrating a step following a step of FIG. 11A.

FIG. 11C is a cross-sectional view illustrating a step following the step of FIG. 11B.

FIG. 12A is a cross-sectional view illustrating a method of manufacturing a display unit according to Modification 2.

FIG. 12B is a cross-sectional view illustrating a step following a step of FIG. 12A.

FIG. 12C is a cross-sectional view illustrating a step following the step of FIG. 12B.

FIG. 13 is an enlarged view of part of FIG. 12B.

FIG. 14A is a cross-sectional view illustrating a step following the step of FIG. 12C.

FIG. 14B is a cross-sectional view illustrating a step following the step of FIG. 14A.

FIG. 15 is a cross-sectional view illustrating a configuration of a display unit according to a second embodiment of the present technology.

FIG. 16A is a cross-sectional view illustrating a method of manufacturing the display unit illustrated in FIG. 15.

FIG. 16B is a cross-sectional view illustrating a step following a step of FIG. 16A.

FIG. 16C is a cross-sectional view illustrating a step following the step of FIG. 16B.

FIG. 17A is a cross-sectional view illustrating a step following the step of FIG. 16C.

FIG. 17B is a cross-sectional view illustrating a step following the step of FIG. 17A.

FIG. 18 is a cross-sectional view illustrating a configuration of a display unit according to a third embodiment of the present technology.

FIG. 19A is a cross-sectional view illustrating a method of manufacturing the display unit illustrated in FIG. 18.

FIG. 19B is a cross-sectional view illustrating a step following a step of FIG. 19A.

FIG. 19C is a cross-sectional view illustrating a step following the step of FIG. 19B.

FIG. 20A is a cross-sectional view illustrating a step following the step of FIG. 19C.

FIG. 20B is a cross-sectional view illustrating a step following the step of FIG. 20A.

FIG. 21 is a perspective view illustrating an appearance of Application example 1.

FIG. 22A is a perspective view illustrating an appearance viewed from the front side of Application example 2.

FIG. 22B is a perspective view illustrating an appearance viewed from the rear side of Application example 2.

FIG. 23 is a perspective view illustrating an appearance of Application example 3.

FIG. 24 is a perspective view illustrating an appearance of Application example 4.

FIG. 25A is a diagram illustrating Application example 5 in a closed state.

FIG. 25B is a diagram illustrating Application example 5 in an open state.

### DETAILED DESCRIPTION

Preferred embodiments of the present technology will be described below in detail with reference to the drawings. The description will be given in the following order.

1. First Embodiment (a display unit having a concave section on a rear surface of a to-be-peeled layer: an example in which an adhesion section and a separation section are formed by patterning an adhesion control layer)
2. Modification 1 (an example in which an adhesion control layer is directly fixed on a first substrate)
3. Modification 2 (an example in which a plurality of adhesion control layers are included)
4. Second Embodiment (a display unit in which an adhesion control layer is provided in a concave section of a to-be-peeled layer)
5. Third Embodiment (a display unit having a flat to-be-peeled layer: an example in which an adhesion section and a separation section are formed by surface treatment of an adhesion control layer)

### 1. First Embodiment

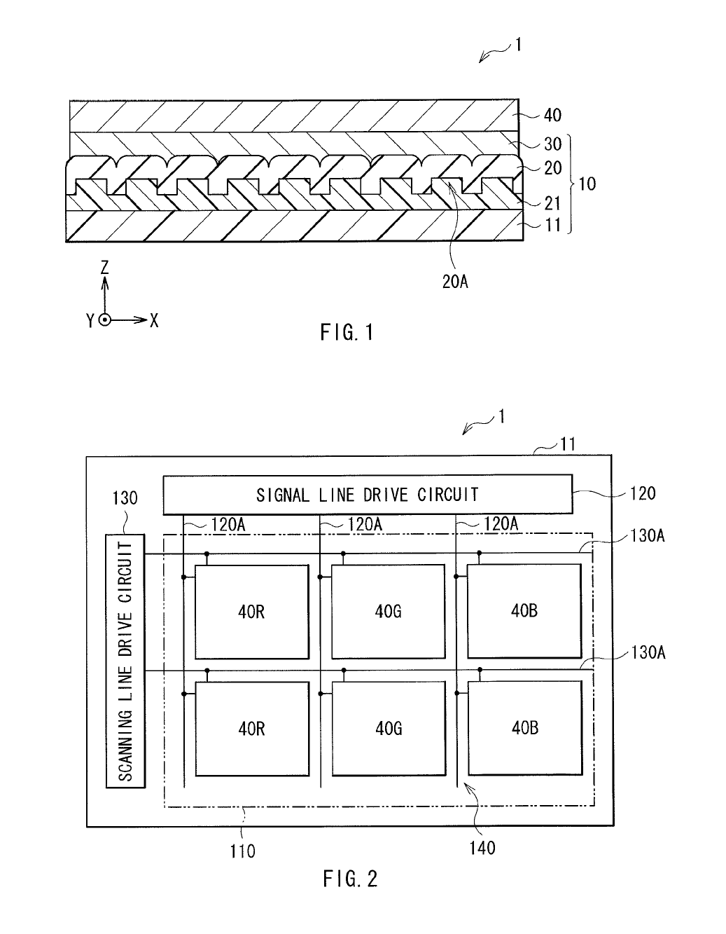

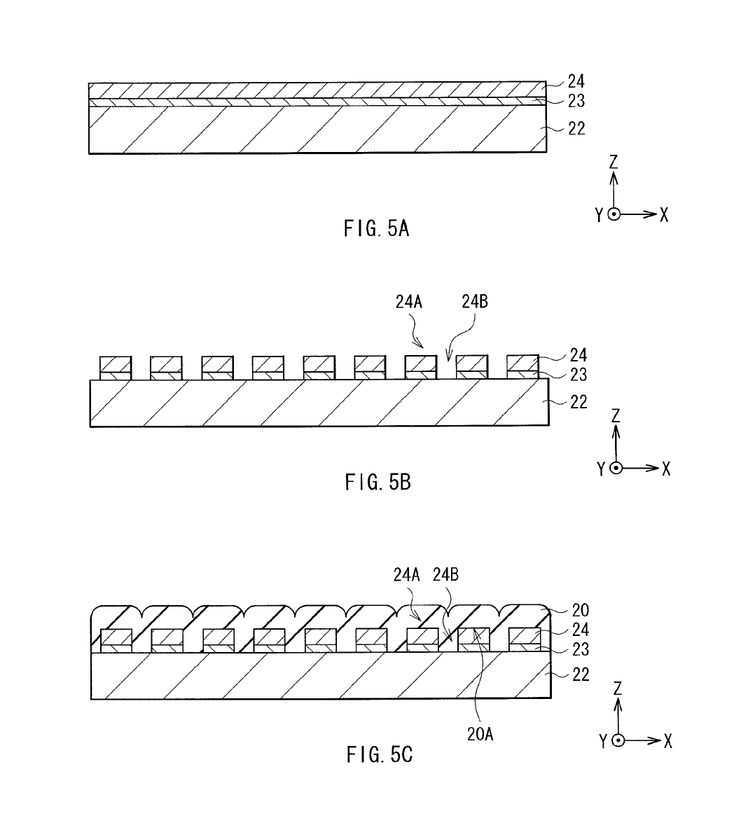

FIG. 1 illustrates a cross-sectional configuration of a display unit (display unit 1) according to a first embodiment of the present technology. The display unit 1 may be, for example, a flexible ultrathin organic light emitting color display. A display layer 40 is provided on a drive substrate 10 (multilayer film substrate). The drive substrate 10 has a second substrate 11 (substrate), a to-be-peeled layer 20, and a TFT layer 30 in this order. The display layer 40 is provided on the TFT layer 30. The to-be-peeled layer 20, the TFT layer 30, and the display layer 40 are formed on a substrate (a first substrate 22 in FIG. 5 described later) different from the second substrate 11. Although a description will be given later, the display unit 1 is manufactured by peeling off the to-be-peeled layer 20 from the first substrate 22 and providing the TFT layer 30 and the display layer 40 on the second substrate 11 together with the to-be-peeled layer 20. It is to be noted that FIG. 1 schematically illustrates a structure of the display unit 1, and dimensions and shapes in FIG. 1 may be different from actual dimensions and actual shapes.

### [Whole Configuration of Display Unit 1]

FIG. 2 illustrates a whole configuration of the display unit 1. The display unit 1 has a display region 110 in the center of the second substrate 11. Around the display region 110, for example, a signal line drive circuit 120 and a scanning line drive circuit 130 that are drivers for displaying an image may be formed.

In the display region 110, a plurality of pixels 40R, 40G, and 40B that are two-dimensionally arranged in a matrix state and a pixel drive circuit 140 for driving the pixels 40R, 40G, and 40B are formed. In the pixel drive circuit 140, a plurality of signal lines 120A are arranged in a column direction, and a plurality of scanning lines 130A are arranged in a row direction. One of the pixels 40R, 40G, and 40B is provided correspondingly to each intersection of each signal line 120A and each scanning line 130A. The pixels 40R, 40G, and 40B are pixels that emit red light, green light, and blue light, respectively. Each signal line 120A is connected to the signal line drive circuit 120, and each scanning line 130A is connected to the scanning line drive circuit 130.

The signal line drive circuit 120 supplies a signal voltage of an image signal corresponding to luminance information supplied from a signal supply source (not illustrated) to the pixels 40R, 40G, and 40B selected through the signal line 120A. The signal voltage from the signal line drive circuit 120 is applied to the signal line 120A.

The scanning line drive circuit 130 may be configured of, for example, a shift resistor or the like that sequentially shifts (transfers) a start pulse in synchronization with an inputted clock pulse. The scanning line drive circuit 130 scans the pixels 40R, 40G, and 40B in units of row upon writing of an image signal into the pixels 40R, 40G, and 40B, and sequentially supplies a scanning signal to each scanning line 130A. The scanning signal from the scanning line drive circuit 130 is supplied to the scanning line 130A.

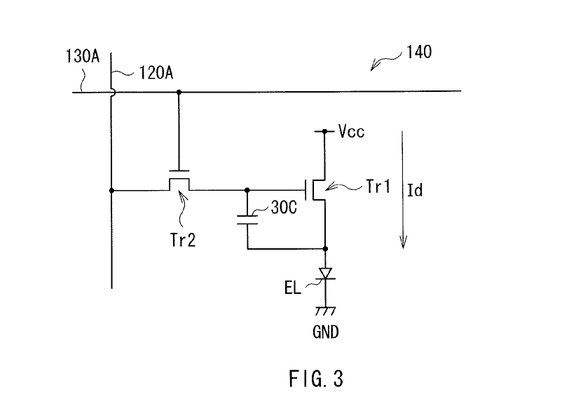

The pixel drive circuit 140 is provided in the TFT layer 30 (FIG. 1). As illustrated in FIG. 3, the pixel drive circuit 140 is an active drive circuit having a drive transistor Tr1, a writing transistor Tr2, a retentive capacity 30 between the drive transistor Tr1 and the writing transistor Tr2, and an organic light emitting element EL.

Next, a description will be given of detailed configurations of the drive substrate 10 and the display layer 40 referring to FIG. 1 again.

### [Configuration of Drive Substrate 10]

The second substrate 11 may be made of, for example, a flexible material having a thickness (Z direction) from 10 to 1000 μm both inclusive. For the second substrate 11, for example, a film made of, for example, polyethylene terephthalate, polyethylene naphthalate, polyether sulfone, polyether imide, polyetherether ketone, polyphenylene sulfide, polyarylate, polyimide, polyamide, polycarbonate, cellulose triacetate, polyolefin, polystyrene, polyethylene, polypropylene, polymethyl methacrylate, polyvinyl chloride, polyvinylidene chloride, an epoxy resin, a phenol resin, a urea resin, a melamine resin, a silicone resin, or an acryl resin, may be used. Also, for the second substrate 11, for example, a metal foil or the like may be used. For example, a material such as a thin layer glass and a thin layer ceramics may be used by thinning the foregoing material to a degree that the foregoing material exhibits flexibility.

The to-be-peeled layer 20 is fixed on the second substrate 11 by an adhesive layer 21. A rear surface (surface opposed to the second substrate 11) of the to-be-peeled layer 20 is provided with a plurality of concave sections 20A, and has a concave-convex shape. In a step of manufacturing the display unit 1, an adhesion control layer (an adhesion control layer 24 in FIG. 5C described later) is provided in the concave sections 20A of the to-be-peeled layer 20, and thereby, adhesion of the to-be-peeled layer 20 to the first substrate 22 is inhibited in the concave sections 20A. On the other hand, in portions (convex sections on the rear surface) other than the concave sections 20A, the TFT layer 30 and the display layer 40 are fixed on the first substrate 22 by the to-be-peeled layer 20. The to-be-peeled layer 20 may be formed by, for example, a CVD (Chemical Vapor Deposition) method. A thickness of the to-be-peeled layer 20 is approximately constant in a plane. Therefore, between any two concave sections 20A adjacent to each other, the front surface of the to-be-peeled layer 20 is depressed as the rear surface of the to-be-peeled layer 20 becomes a convex shape. In order to suppress influence of such concavity and convexity of the front surface of the to-be-peeled layer 20 on the TFT layer 30 or the display layer 40 as an upper layer, a planarizing layer (not illustrated) may be provided between the to-be-peeled layer 20 and the TFT layer 30. The to-be-peeled layer 20 may be made of, for example, silicon nitride (SiNₓ), silicon oxide (SiO₂), aluminum oxide (Al₂O₃), polyimide (PI), polyether sulfone (PES), polycarbonate (PC), polyethylene terephthalate (PET), and/or the like having a thickness of about 5 μm.

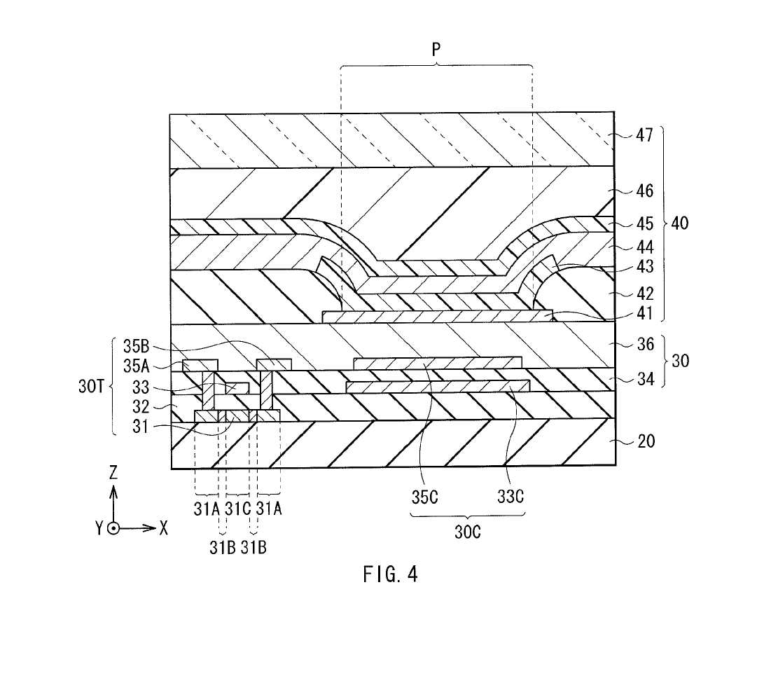

As illustrated in FIG. 4, the TFT layer 30 includes a transistor 30T (the foregoing drive transistor Tr1 and the foregoing writing transistor Tr2) and the retentive capacity 30C. The pixel drive circuit 140 is configured of the transistor 30T and the retentive capacity 30C. The TFT layer 30 is provided with the signal line 120A and the scanning line 130A as well (not illustrated). The transistor 30T may be a top-gate-type transistor having a semiconductor film 31, a gate insulating film 32, and a gate electrode 33 in this order from the second substrate 11 (to-be-peeled layer 20) side. Source-drain electrodes 35A and 35B are electrically connected to the semiconductor film 31. A first protective film 34 is provided between the source-drain electrodes 35A and 35B and the gate electrode 33. The source-drain electrodes 35A and 35B are connected to the semiconductor film 31 through connection holes penetrating through the first protective film 34. The semiconductor film 31 may be made of, for example, polysilicon, and has a pair of LDD (Low Dope Drain) regions 31B and a pair of contact regions 31A with a channel region 31C in between. A lower electrode 33C of the retentive capacity 30C may be provided, for example, in a layer same as that of the gate electrode 33. An upper electrode 35C of the retentive capacity 30C may be provided, for example, in a layer same as that of the source-drain electrodes 35A and 35B. The upper electrode 35C and the source-drain electrodes 35A and 35B may be covered with a planarizing film 36 made of an insulating resin material such as polyimide.

### [Configuration of Display Layer 40]

The display layer 40 has a first electrode 41 as an anode electrode, an organic film 43 including a light emitting layer, and a second electrode 44 as a cathode electrode from the second substrate 11 (planarizing film 36) side. In the display layer 40, the second electrode 44 is covered with a second protective film 45, and an opposing substrate 47 is provided on the second protective film 45 with a sealing film 46 in between. The organic film 43 may have, for example, a hole injection layer, a hole transport layer, a light emitting layer, and an electron transport layer in order from the first electrode 41 side. The light emitting layer may be provided for each of the pixels 40R, 40G, and 40B, or may be provided commonly to the respective pixels 40R, 40G, and 40B. The layers other than the light emitting layer may be provided as necessary. Each of the pixels 40R, 40G, and 40B is separated by a pixel separation film 42. A pixel region P (light emitting region) of the pixels 40R, 40G, and 40B is defined by the pixel separation film 42. In order to prevent the concavity and convexity of the front surface of the to-be-peeled layer 20 from influencing display quality, the pixel region P may be preferably provided in a position opposed to the concave section 20A of the to-be-peeled layer 20. Thereby, the pixels 40R, 40G, and 40B are allowed to be provided in a location other than the portions where the front surface of the to-be-peeled layer 20 is depressed. The opposing substrate 47 may have, for example, color filters corresponding to the pixels 40R, 40G, and 40B and a black matrix between the color filters (not illustrated). In the display unit 1, since an image is displayed on the opposing substrate 47 side, a transparent material is used for the opposing substrate 47. Except for this point, the opposing substrate 47 may be made of a material similar to that of the second substrate 11.

### [Method of Manufacturing Display Unit 1]

The display unit 1 as described above may be manufactured, for example, as follows.

First, as illustrated in FIG. 5A, a close-contact layer 23 (first close-contact layer) and an adhesion control layer 24 may be formed in this order on the first substrate 22 made of, for example, glass. Thereafter, the adhesion control layer 24 and the close-contact layer 23 may be patterned by, for example, a photolithography method and an etching method (FIG. 5B). Thereby, a separation section 24A in which the adhesion control layer 24 remains and an adhesion section 24B in which the front surface of the first substrate 22 is exposed are formed. The adhesion section 24B is a section that adheres and fixes the first substrate 22 to the to-be-peeled layer 20. On the other hand, in the separation section 24A, adhesiveness of the to-be-peeled layer 20 with respect to the first substrate 22 (adhesion control layer 24) is lower than that in the adhesion section 24B. That is, the separation section 24A inhibits adhesion of the to-be-peeled layer 20 to the first substrate 22. In the separation section 24A, the to-be-peeled layer 20 is easily separated from the first substrate 22 (adhesion control layer 24). Although details will be described later, in this embodiment, since the adhesion section 24B and the separation section 24A are provided in the adhesion control layer 24 as described above, the TFT layer 30 and the display layer 40 formed on the first substrate 22 are allowed to be moved to the second substrate 11 without performing, for example, laser irradiation or the like.

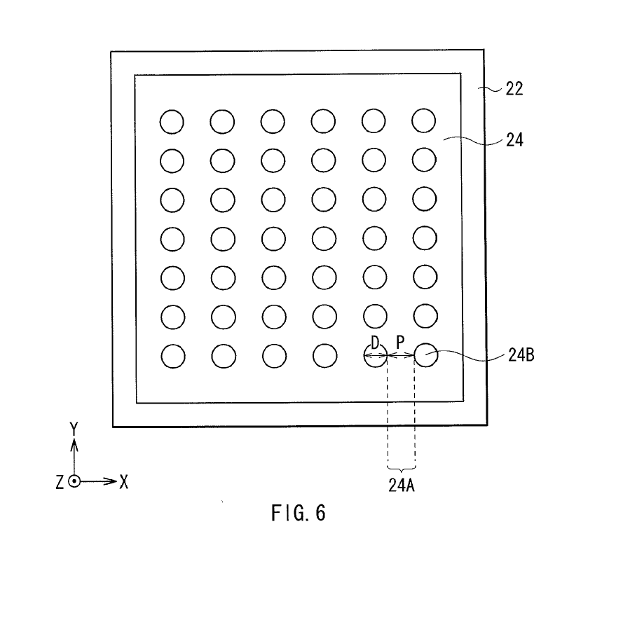

More specifically, the separation section 24A is configured of a front surface and side surfaces of the patterned adhesion control layer 24, and the adhesion section 24B is configured of the front surface of the first substrate 22. As illustrated in FIG. 6, the adhesion section 24B may be provided, for example, in a circular pattern. Diameter D of the adhesion section 24B may be, for example, 3 μm, and pitch P (width of the separation section 24A) between any two adhesion sections 24B adjacent to each other may be, for example, 10 μm. In order to allow the to-be-peeled layer 20 to be easily peeled off from the first substrate 22, the adhesion section 24B may be preferably small. For example, the diameter D may be preferably equal to or less than several tens of nanometers.

For the first substrate 22, a substrate thicker than the second substrate 11 may be preferably used. Further, the first substrate 22 may be preferably made of a rigid material such as glass, quartz, and silicon. The close-contact layer 23 is used to fix the adhesion control layer 24 to the first substrate 22, and has adhesiveness with respect to the first substrate 22 and the adhesion control layer 24. The adhesion control layer 24 changes adhesiveness between the first substrate 22 and the to-be-peeled layer 20 by the separation section 24A and the adhesion section 24B. In this case, the adhesion control layer 24 having adhesiveness with respect to the to-be-peeled layer 20 lower than adhesiveness with respect to the first substrate 22 is used, and the adhesion control layer 24 is patterned and thereby, the adhesion section 24B is formed. The adhesion control layer 24 may not be adhered to the to-be-peeled layer 20 at all. Adhesiveness between one of the first substrate 22, the close-contact layer 23, the adhesion control layer 24, and the to-be-peeled layer 20 and another one thereof is related to tensile bond strength (JISK6849 (1994)) between materials configuring the foregoing layers. Tensile adhesion strength between the to-be-peeled layer 20 and the adhesion control layer 24 may be preferably equal to or less than 1 N/mm². Further, tensile bond strength between the first substrate 22 and the to-be-peeled layer 20, tensile bond strength between the first substrate 22 and the close-contact layer 23, and tensile bond strength between the close-contact layer 23 and the adhesion control layer 24 may each be preferably equal to or larger than 5 N/mm². For the close-contact layer 23, for example, metal such as chromium (Cr) and titanium (Ti) may be used. For the adhesion control layer 24, for example, metal such as gold (Au), silver (Ag), copper (Cu), and nickel (Ni), a fluorine-based silane coupling agent, an alkyl-based silane coupling agent, or the like may be used. A thickness of the close-contact layer 23 may be, for example, 20 nm. A thickness of the adhesion control layer 24 may be, for example, 50 nm. The close-contact layer 23 and the adhesion control layer 24 may be formed by, for example, a sputtering method or an evaporation method.

After the adhesion control layer 24 and the close-contact layer 23 are patterned, as illustrated in FIG. 5C, the to-be-peeled layer 20 made of, for example, silicon nitride may be formed on the separation section 24A and the adhesion section 24B. The to-be-peeled layer 20 may be formed by, for example, a CVD method. At this time, in the adhesion section 24B, the to-be-peeled layer 20 is in contact with the first substrate 22 and is fixed to the first substrate 22. On the other hand, in the separation section 24A, the adhesion control layer 24 exists between the to-be-peeled layer 20 and the first substrate 22 (concave section 20A). Thereby, in the separation section 24A, adhesion of the to-be-peeled layer 20 with respect to the first substrate 22 is inhibited. That is, adhesiveness in the concave section 20A of the to-be-peeled layer 20 with respect to the first substrate 22 is different from the adhesiveness in the other sections with respect to the first substrate 22.

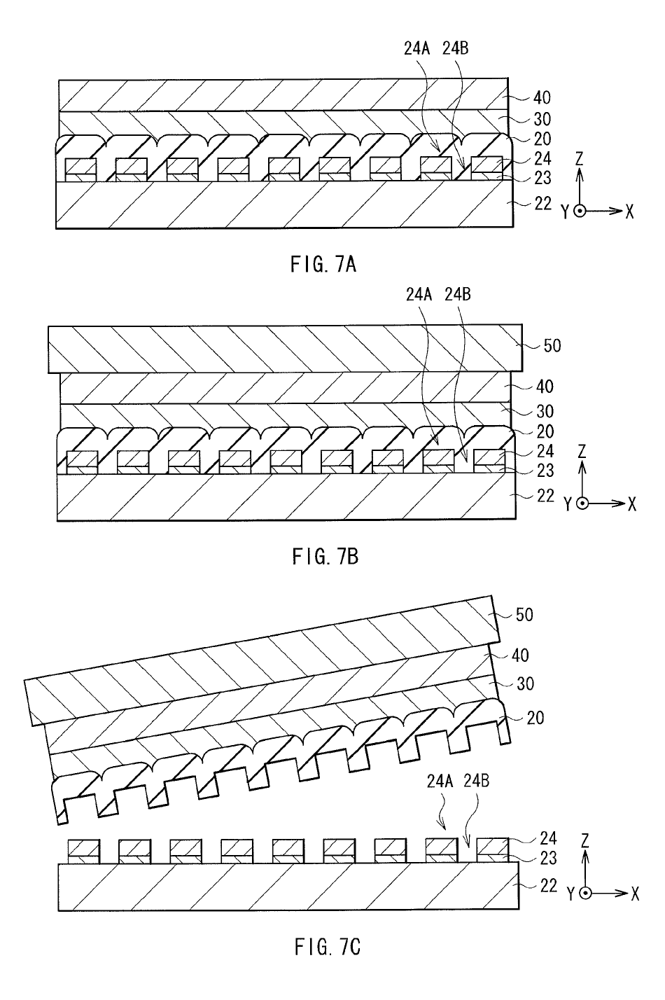

After the to-be-peeled layer 20 is provided, as illustrated in FIG. 7A, the TFT layer 30 and the display layer 40 are formed on the to-be-peeled layer 20. Specifically, first, for example, amorphous silicon (a-Si) having a thickness of 50 nm may be formed on the to-be-peeled layer 20 by a CVD method, the resultant is subsequently heated in inactive gas such as argon (Ar) to detach hydrogen (H₂). Next, the amorphous silicon is subjected to, for example, excimer laser annealing treatment to make crystal growth. Thereafter, the resultant is patterned by a photolithography method and an etching method, and the semiconductor film 31 made of polysilicon (FIG. 4) is formed.

Subsequently, the gate insulating film 32 made of, for example, silicon oxide having a thickness of, for example, 100 nm may be formed on the semiconductor film 31 and the to-be-peeled layer 20. Next, aluminum (Al) having a thickness of, for example, 200 nm may be formed on the gate insulating film 32. Thereafter, the resultant is patterned by a photolithography method and an etching method, and the gate electrode 33 and the lower electrode 33C are formed. Subsequently, the whole surface of the first substrate 22 (to-be-peeled layer 20) may be doped with phosphorus at a low concentration by, for example, ion implantation to form the LDD region 31B in the semiconductor film 31. Next, the gate electrode 33 and the LDD region 31B of the semiconductor film 31 are covered with a resist, the whole surface of the first substrate 22 (to-be-peeled layer 20) may be doped with phosphorus at a high concentration by, for example, ion implantation, the resist may be subsequently peeled off, and activation treatment, for example, with the use of flashlamp annealing may be performed. Thereby, the contact region 31A and the channel region 31C are formed in the semiconductor film 31.

Subsequently, the first protective film 34 made of, for example, silicon nitride having a thickness of, for example, 200 nm may be formed on the whole surface of the first substrate 22 by a CVD method. Next, connection holes for connecting the contact region 31A of the semiconductor film 31 with the source-drain electrodes 35A and 35B may be formed in the first protective film 34 by, for example, a photolithography method and a dry etching method. After the connection holes are formed in the first protective film 34, for example, an aluminum film having a thickness of, for example, 200 nm may be formed on the first protective film 34 by a sputtering method. The resultant is patterned to form the source-drain electrodes 35A and 35B and the upper electrode 35C. After the transistor 30T and the retentive capacity 30C are formed in such a manner, the transistor 30T and the retentive capacity 30C may be covered with the planarizing film 36 made of, for example, a photosensitive resin, and thereby, the TFT layer 30 is formed. A connection hole (not illustrated) for connecting the first electrode 41 of the display layer 40 with the transistor 30T may be formed in the planarizing film 36 by, for example, a photolithography method in advance.

After the TFT layer 30 is formed, the display layer 40 may be formed, for example, as below. First, for example, a titanium film and an aluminum alloy film may be formed by, for example, a sputtering method. Thereafter, the resultant may be formed into a prescribed shape by, for example, a photolithography method and dry etching to form the first electrode 41. Next, the planarizing film 36 and the first electrode 41 are coated with a photosensitive insulating material such as polyimide, and the pixel separation film 42 may be formed by, for example, a photolithography method.

After the pixel separation film 42 is formed, the organic film 43 may be formed by, for example, an evaporation method or printing. Next, on the organic film 43, the second electrode 44 may be formed by, for example, an evaporation method, and the second protective film 45 may be formed by, for example, a CVD (Chemical Vapor Deposition) method or a sputtering method in this order. After the second protective film 45 is formed, the opposing substrate 47 on which components such as the color filters and the black matrix are formed is adhered onto the second protective film 45 with the sealing film 46 in between. Thereby, the display layer 40 is formed.

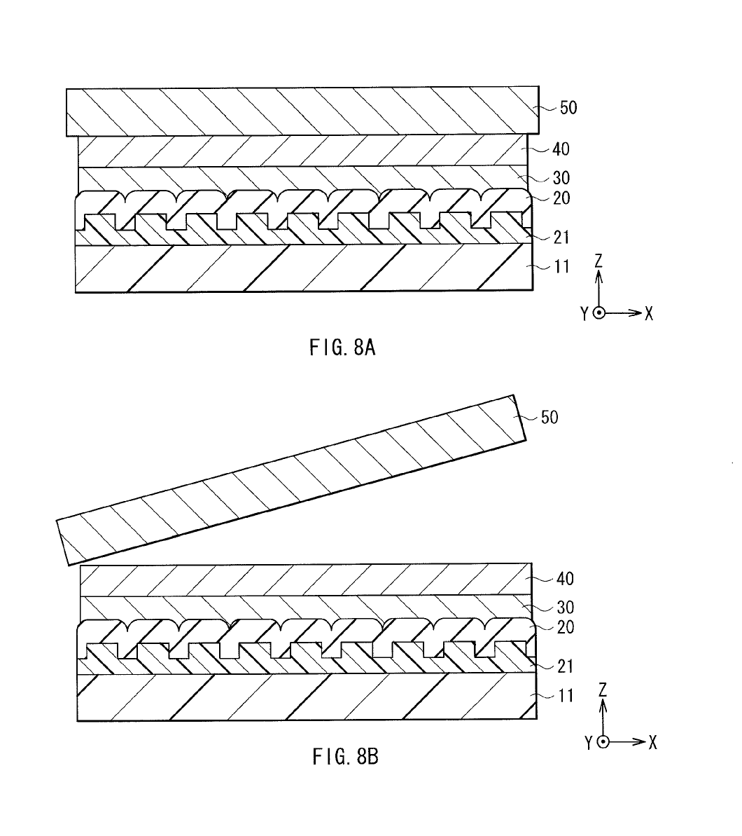

After the TFT layer 30 and the display layer 40 are laminated on the to-be-peeled layer 20 as described above, as illustrated in FIG. 7B, a transfer sheet 50 made of, for example, silicone rubber may be adhered to the display layer 40 (opposing substrate 47). Next, as illustrated in FIG. 7C, the to-be-peeled layer 20 may be peeled off from the first substrate 22 together with the TFT layer 30 and the display layer 40, for example, by using a physical means such as a hand. At this time, the to-be-peeled layer 20 is separated from the first substrate 22 (adhesion control layer 24) at the interface between the to-be-peeled layer 20 and the adhesion control layer 24 in the separation section 24A. The to-be-peeled layer 20 is supported by the transfer sheet 50 together with the TFT layer 30 and the display layer 40. After the whole rear surface of the to-be-peeled layer 20 is peeled off from the first substrate 22, as illustrated in FIG. 8A, the to-be-peeled layer 20, the TFT layer 30, and the display layer 40 are fixed on the second substrate 11 (second substrate) by using the adhesion layer 21. Finally, the transfer sheet 50 is peeled off from the display layer 40 (FIG. 8B), and accordingly, the display unit 1 illustrated in FIG. 1 to FIG. 4 is completed.

In the foregoing method of manufacturing the display unit 1, the separation section 24A and the adhesion section 24B are provided in the adhesion control layer 24. Therefore, after the TFT layer 30 and the display layer 40 are formed on the first substrate 22, the to-be-peeled layer 20 is allowed to be peeled off from the first substrate 22 without performing treatment such as laser irradiation. Therefore, the TFT layer 30 and the display layer 40 are allowed to be prevented from being degraded on the first substrate 22.

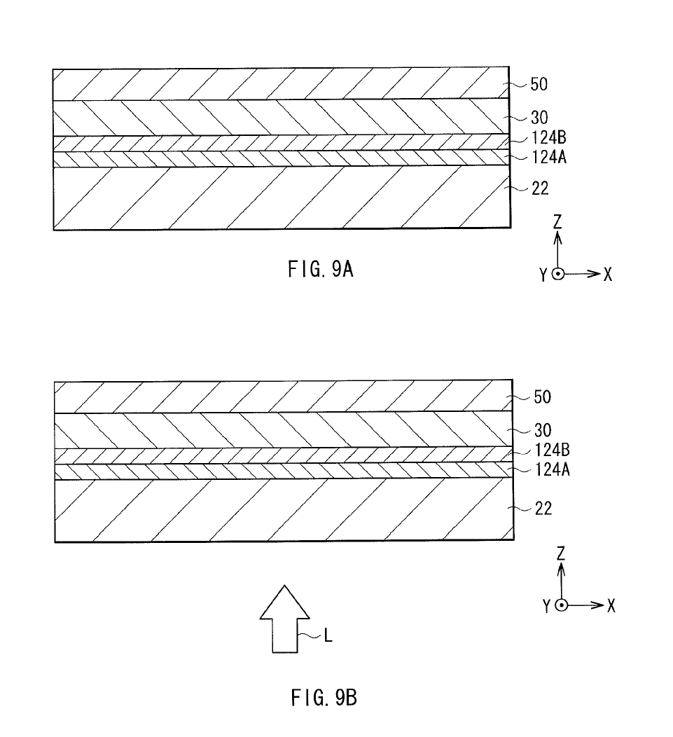

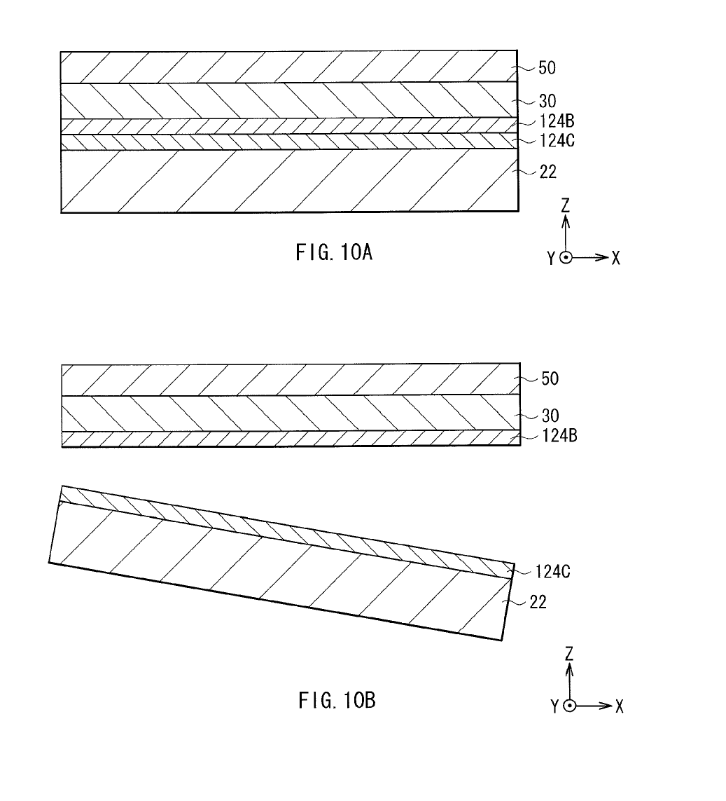

FIG. 9A to FIG. 10B illustrate a method of manufacturing a display unit according to a comparative example. In this method, first, a metal layer 124A, an oxidation layer 124B, and the TFT layer 30 are formed on the first substrate 22 in this order, and subsequently, the transfer sheet 50 is adhered to the TFT layer 30 (FIG. 9A). Next, laser light L is irradiated from the first substrate 22 side (FIG. 9B) to oxidize the metal layer 124A. Thereby, a brittle metallic oxide layer 124C is formed (FIG. 10A). After the metallic oxide layer 124C is formed, the TFT layer 30 is peeled off from the first substrate 22 by a physical means. Accordingly, the first substrate 22 is separated from the oxidation layer 124B from inside of the metallic oxide layer 124C or at the interface between the metallic oxide layer 124C and the oxidation layer 124B (FIG. 10B). Subsequently, after the oxidation layer 124B and the TFT layer 30 are fixed to a support substrate, the transfer sheet 50 is peeled off from the TFT layer 30, the display layer 40 is formed on the TFT layer 30, and accordingly, the display unit is completed.

In the foregoing method, after the TFT layer 30 is formed on the first substrate 22, the metallic oxide layer 124C is formed by irradiating the laser light L. Therefore, heat generated by laser irradiation may degrade the TFT layer 30. Further, on the first substrate 22, the display layer 40 having low heat resistance is not allowed to be formed. Further, since the laser light L is used, manufacturing cost is increased. In addition thereto, the oxidation layer 124B has a low protective function with respect to moisture and/or the like. Therefore, in the case where the TFT layer 30 is provided on the support substrate, there is a possibility that the oxidation layer 124B does not sufficiently protect the TFT layer 30.

On the other hand, in the display unit 1, the separation section 24A and the adhesion section 24B are provided in the adhesion control layer 24. Thereby, after the to-be-peeled layer 20 is fixed to the first substrate 22 in the adhesion section 24B, and the TFT layer 30 and the display layer 40 are formed on the to-be-peeled layer 20, the to-be-peeled layer 20 is allowed to be easily separated from the first substrate 22 due to the separation section 24A without performing laser irradiation or the like. Therefore, the TFT layer 30 is prevented from being degraded, for example, by laser irradiation and/or the like. Further, the display layer 40 having low heat resistance is allowed to be formed on the first substrate 22. Further, since laser irradiation is not necessary, manufacturing cost is allowed to be decreased. In addition thereto, an oxidation layer is not necessary, and a material having a high protective function with respect to moisture and/or the like such as silicon nitride may be used for the to-be-peeled layer 20.

### [Operation of Display Unit 1]

In the display unit 1, a scanning signal is supplied from the scanning line drive circuit 130 to the pixels 40R, 40G, and 40B through the gate electrode of the writing transistor Tr2. An image signal from the signal line drive circuit 120 is retained in the retentive capacity 30C through the writing transistor Tr2. That is, the drive transistor Tr1 is controlled to be turned on or off according to the signal retained in the retentive capacity 30C. Thereby, a drive current is injected into the pixels 40R, 40G, and 40B, electron-hole recombination occurs, and accordingly, light is emitted. The light passes through the second electrode 44, the second protective film 45, the sealing film 46, and the opposing substrate 47, and is extracted.

### [Function and Effect of Display Unit 1]

In this embodiment, at the time of manufacturing the display unit 1, since the separation section 24A and the adhesion section 24B are provided in the adhesion control layer 24, the first substrate 22 and the to-be-peeled layer 20 may be easily separated from each other without performing a treatment such as laser irradiation.

As described above, in this embodiment, since the separation section 24A and the adhesion section 24B are provided in the adhesion control layer 24, the TFT layer 30 and the display layer 40 are allowed to be moved from the first substrate 22 onto the second substrate 11 without performing a treatment such as laser irradiation. Therefore, degradation of the TFT layer 30 and the display layer 40 is allowed to be suppressed.

A description will be given of modifications of the foregoing embodiment and other embodiments. In the following description, for the same components as the components in the foregoing embodiment, the same referential symbols are affixed thereto, and the description thereof will be omitted as appropriate.

### [Modification 1]

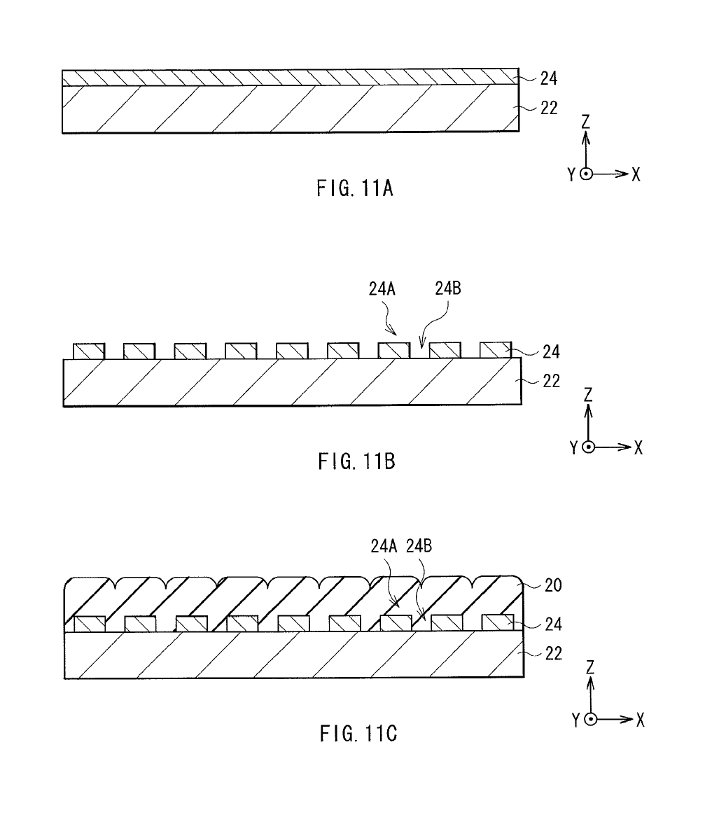

FIG. 11A to FIG. 11C illustrate another example (Modification 1) of the method of manufacturing the display unit 1 described in the foregoing embodiment. In this method, the adhesion control layer 24 is fixed to the first substrate 22 without using a close-contact layer. In Modification 1, the display unit 1 is manufactured as in the foregoing first embodiment except for the foregoing point.

First, as illustrated in FIG. 11A, the adhesion control layer 24 is formed on the first substrate 22. The adhesion control layer 24 is fixed to the first substrate 22 with the rear surface thereof being in contact with the first substrate 22. On the other hand, on the front surface thereof, adhesiveness with respect to the to-be-peeled layer 20 is lower than adhesiveness with respect to the first substrate 22. For the adhesion control layer 24, for example, a metal such as nickel, a fluorine-based silane coupling agent, an alkyl-based silane coupling agent, or the like may be used. Next, as illustrated in FIG. 11B, the adhesion control layer 24 is patterned to provide the separation section 24A and the adhesion section 24B. Thereafter, the to-be-peeled layer 20 is formed in the separation section 24A and the adhesion section 24B (FIG. 11C). The to-be-peeled layer 20 is fixed to the first substrate 22 in the adhesion section 24B, and adhesion with respect to the first substrate 22 is inhibited in the separation section 24A. For the to-be-peeled layer 20, for example, an organic material such as polyimide, polyether sulfone, polycarbonate, and polyethylene terephthalate or the like may be used.

After the to-be-peeled layer 20 is formed, as in the foregoing embodiment, the TFT layer 30 and the display layer 40 are formed on the to-be-peeled layer 20, the to-be-peeled layer 20, the TFT layer 30, and the display layer 40 are moved onto the second substrate 11 with the use of the transfer sheet 50, and thereby, the display unit 1 is completed. The display unit 1 may be manufactured without using a close-contact layer as described above.

### [Modification 2]

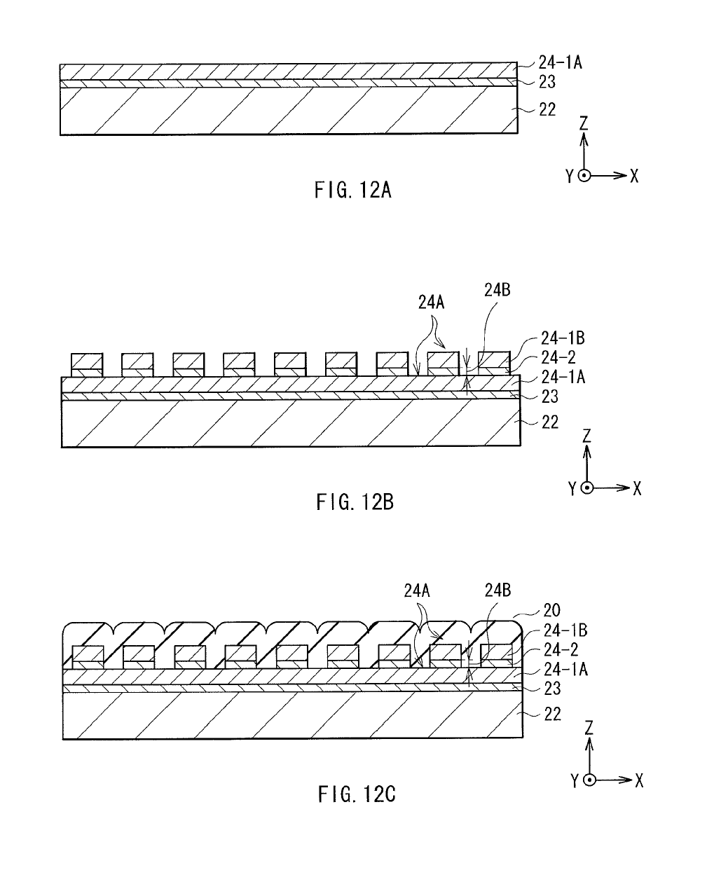

FIG. 12A to FIG. 14C illustrate still another example (Modification 2) of the method of manufacturing the display unit 1 described in the foregoing embodiment. In this method, the separation section 24A and the adhesion section 24B are configured of a plurality of adhesion control layers (adhesion control layers 24-1A, 24-1B, and 24-2). In Modification 2, the display unit is manufactured as in the above-described first embodiment except for the foregoing point.

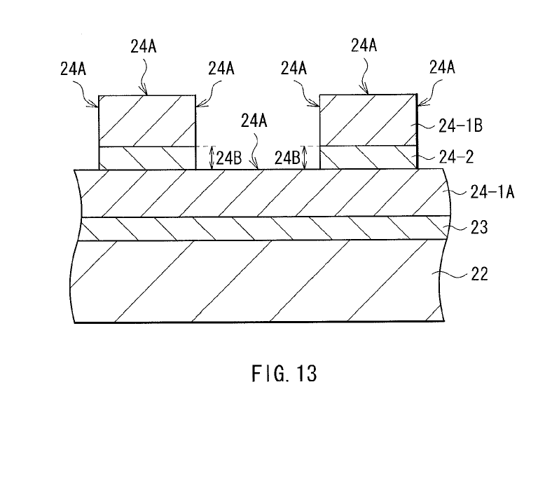

First, as illustrated in FIG. 12A, the close-contact layer 23 and the adhesion control layer 24-1A are formed on the first substrate 22 in this order. The adhesion control layer 24-1A (first adhesion control layer) configures the separation section 24A. For the adhesion control layer 24-1A, a material having adhesiveness with respect to the to-be-peeled layer 20 that is lower than adhesiveness with respect to the first substrate 22 is used. Next, the adhesion control layer 24-2 (second adhesion control layer) is formed on the adhesion control layer 24-1A. Thereafter, the adhesion control layer 24-2 is covered with the adhesion control layer 24-1B (third adhesion control layer), and the adhesion control layer 24-1B and the adhesion control layer 24-2 are patterned (FIG. 12B). At this time, the adhesion control layer 24-1A is not patterned, and may be provided, for example, on the whole surface of the first substrate 22. The adhesion control layer 24-2 configures the adhesion section 24B, and the adhesion control layer 24-1B configures the separation section 24A. The adhesion control layer 24-2 is adhered to the adhesion control layer 24-1A, and thereby is fixed to the first substrate 22. Further, the adhesion control layer 24-2 also has adhesiveness with respect to the to-be-peeled layer 20. On the other hand, for the adhesion control layer 24-1B, a material having adhesiveness with respect to the to-be-peeled layer 20 that is lower than adhesiveness with respect to the adhesion control layer 24-2 is used. Therefore, by patterning the adhesion control layer 24-1B and the adhesion control layer 24-2, the adhesion control layer 24-1B and the adhesion control layer 24-2 are provided on part of the surface of the adhesion control layer 24-1A, the separation section 24A is formed of the adhesion control layers 24-1A and 24-1B, and the adhesion section 24B is formed of the adhesion control layer 24-2. Specifically, as illustrated in FIG. 13, the separation section 24A is configured of the surface of the adhesion control layer 24-1A and the front surface and side surfaces of the adhesion control layer 24-1B, and the adhesion section 24B is configured of only side surfaces of the adhesion control layer 24-2. As described above, the adhesion section 24B is formed by covering the front surface of the adhesion control layer 24-2 with the adhesion control layer 24-1B and exposing only side surfaces of the adhesion control layer 24-2. Thereby, size of the adhesion section 24B is allowed to be adjusted by a film thickness (for example, in nanometer) of the adhesion control layer 24-2. That is, it becomes possible to reduce the size of the adhesion section 24B and to easily peel off the to-be-peeled layer 20 from the first substrate 22. For the adhesion control layers 24-1A and 24-1B, for example, metal such as gold, silver, copper, and nickel may be used. For the adhesion control layer 24-2, for example, metal such as chromium and titanium may be used.

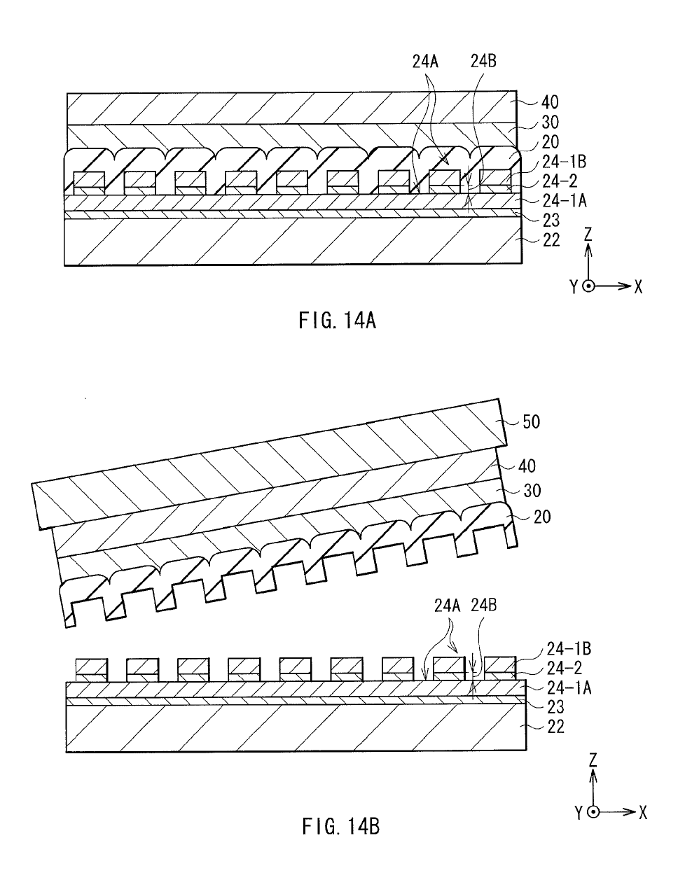

After the adhesion control layer 24-1B and the adhesion control layer 24-2 are patterned, as illustrated in FIG. 12C, the to-be-peeled layer 20 is formed in the separation section 24A and the adhesion section 24B. Next, as in the foregoing embodiment, the TFT layer 30 and the display layer 40 are formed on the to-be-peeled layer 20 (FIG. 14A), the to-be-peeled layer 20 is subsequently peeled off from the first substrate 22 with the use of the transfer sheet 50 (FIG. 14B). Finally, the TFT layer 30 and the display layer 40 are fixed onto the second substrate 11 together with the to-be-peeled layer 20, and thereby, the display unit 1 is completed. As described above, the separation section 24A and the adhesion section 24B may be configured of the plurality of adhesion control layers 24-1A, 24-1B, and 24-2, and thereby, size of the separation section 24A or size the adhesion section 24B is allowed to be controlled more precisely.

### Second Embodiment

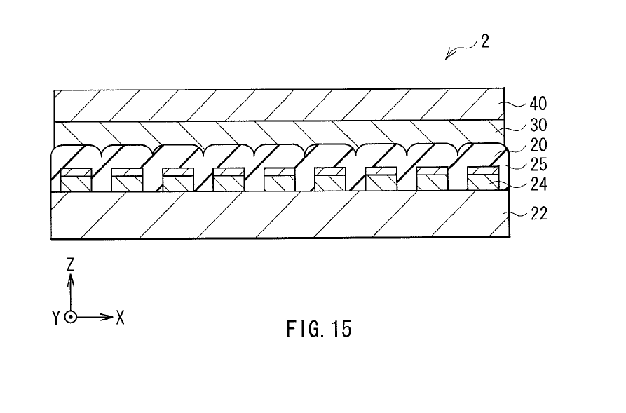

FIG. 15 illustrates a cross-sectional configuration of a display unit (display unit 2) according to a second embodiment of the present technology. In the display unit 2, the adhesion control layer 24 and a close-contact layer (close-contact layer 25) are provided in the concave section 20A located on the rear surface of the to-be-peeled layer 20. Except for this point, the display unit 2 has a configuration similar to that of the display unit 1 according to the foregoing first embodiment, and functions and effects thereof are similar to those of the foregoing first embodiment.

The close-contact layer 25 (second close-contact layer) is provided between the adhesion control layer 24 and the to-be-peeled layer 20. The close-contact layer 25 is patterned together with the adhesion control layer 24, and a plane shape thereof is the same as the plane shape of the adhesion control layer 24. The close-contact layer 25 is used to fix the adhesion control layer 24 to the to-be-peeled layer 20, and has adhesiveness with respect to the to-be-peeled layer 20 and the adhesion control layer 24. The close-contact layer 25 may be made of, for example, chromium, titanium, or the like.

The foregoing display unit 2 having the close-contact layer 25 and the adhesion control layer 24 may be manufactured, for example, as follows.

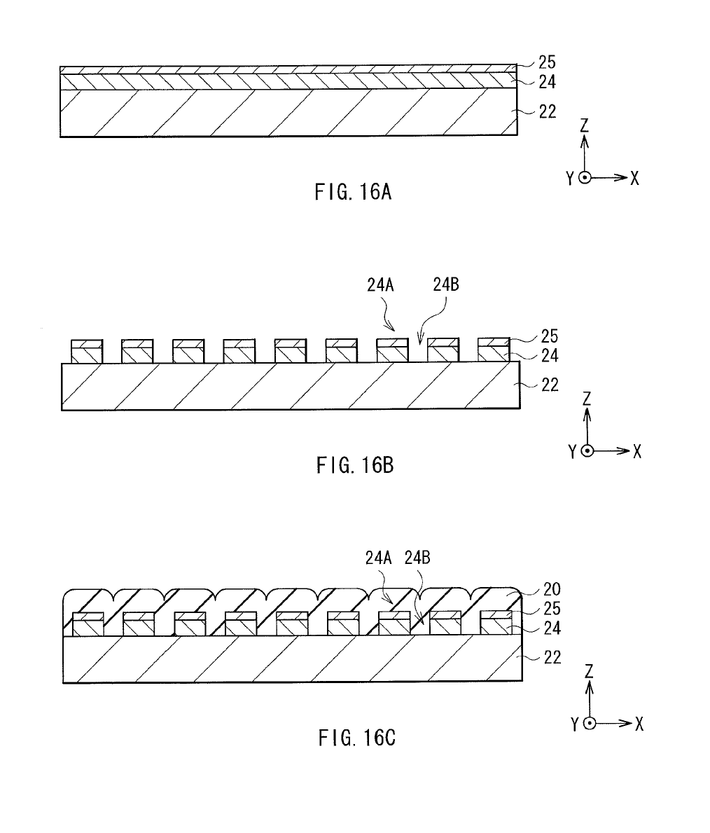

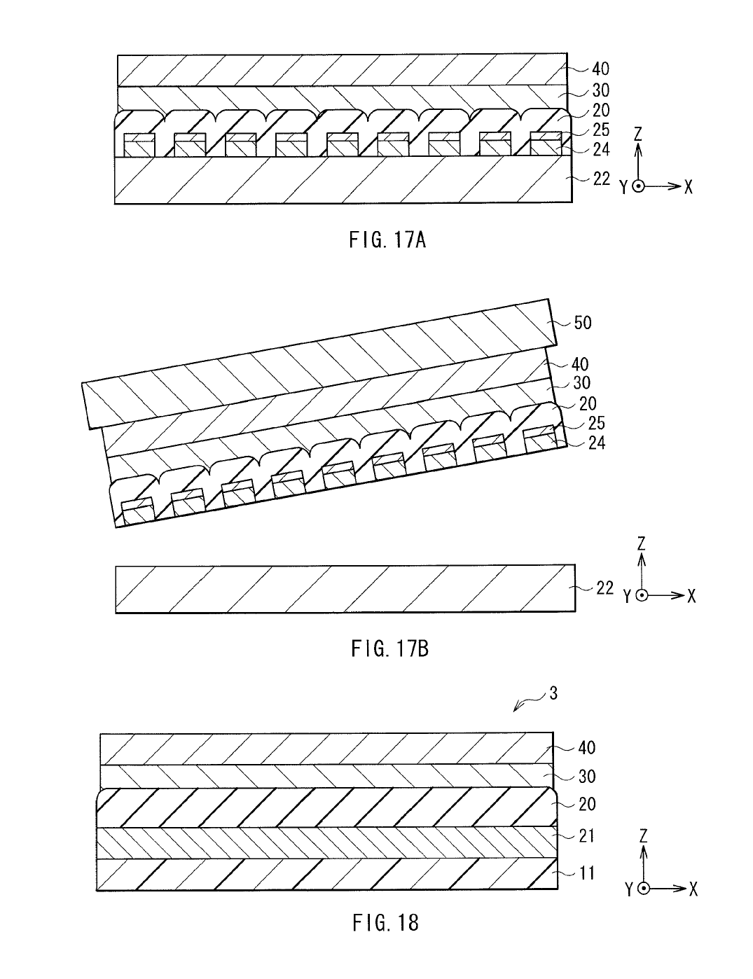

First, as illustrated in FIG. 16A, after the adhesion control layer 24 and the close-contact layer 25 are formed on the first substrate 22 in this order, the close-contact layer 25 and the adhesion control layer 24 are patterned (FIG. 16B). Thereby, the separation section 24A and the adhesion section 24B are formed. Next, as illustrated in FIG. 16C, the to-be-peeled layer 20 is formed on the separation section 24A and the adhesion section 24B. Subsequently, the TFT layer 30 and the display layer 40 are formed on the to-be-peeled layer 20 (FIG. 17A), and thereafter, the to-be-peeled layer 20 is peeled off from the first substrate 22 by using the transfer sheet 50 (FIG. 17B). At this time, since the adhesion control layer 24 is fixed to the to-be-peeled layer 20 by the close-contact layer 25, the adhesion control layer 24 is also peeled off from the first substrate 22 together with the to-be-peeled layer 20. That is, the to-be-peeled layer 20 is peeled off from the first substrate 22 in a state that the close-contact layer 25 and the adhesion control layer 24 are provided in the concave section 20A. Finally, the TFT layer 30 and the display layer 40 are fixed onto the second substrate 11 together with the to-be-peeled layer 20, and thereby, the display unit 2 is completed.

### Third Embodiment

FIG. 18 illustrates a cross-sectional configuration of a display unit (display unit 3) according to a third embodiment of the present technology. In the display unit 3, the to-be-peeled layer 20 is flat, and does not have a concave section on the rear surface thereof. Except for this point, the display unit 3 has a configuration similar to that of the display unit 1 according to the foregoing first embodiment, and functions and effects thereof are similar to those of the foregoing first embodiment.

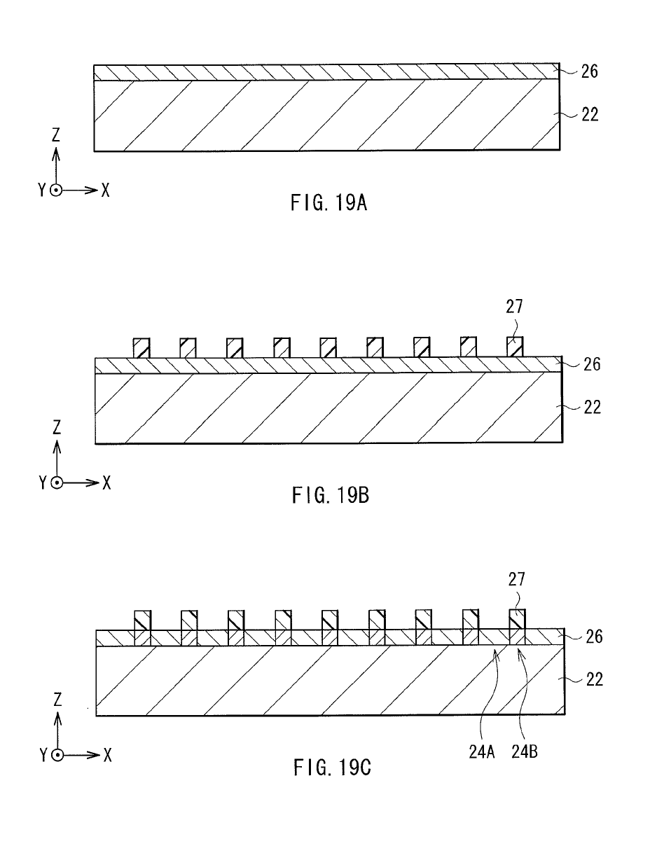

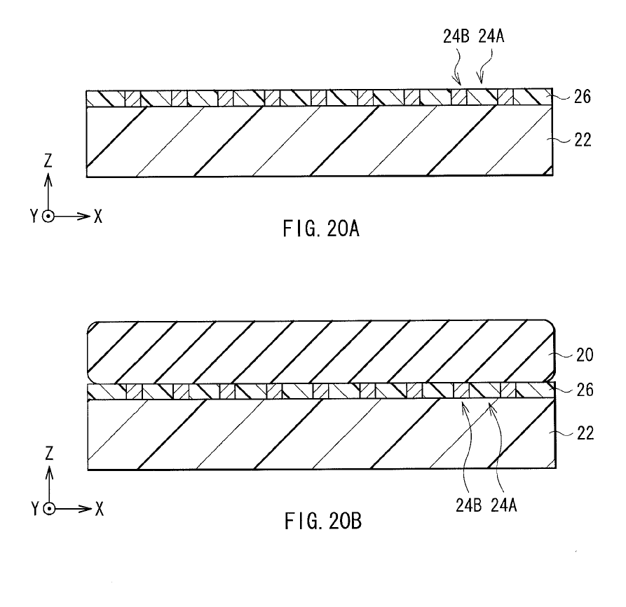

The display unit 3 may be manufactured, for example, as follows (FIG. 19A to FIG. 20B).

First, as illustrated in FIG. 19A, an adhesion control layer 26 made of, for example, copper (Cu) may be formed on the first substrate 22. The adhesion control layer 26 has adhesiveness with respect to the first substrate 22 and the to-be-peeled layer 20 (adhesion section 24B). Next, a resist 27 is provided on the adhesion control layer 26, and thereafter, the provided resist 27 is patterned (FIG. 19B). Subsequently, oxidation treatment by, for example, oxidation treatment by oxygen plasma may be performed on the surface of the adhesion control layer 26 to oxidize a portion of the adhesion control layer 26 exposed from the resist 27. Thereby, the oxidized portion of the adhesion control layer 26 becomes brittle, and the separation section 24A is formed in the adhesion control layer 26 (FIG. 19C). After performing the oxidation treatment on the adhesion control layer 26, the resist 27 is removed (FIG. 20A), and the to-be-peeled layer 20 is formed on the adhesion control layer 26 (FIG. 20B). At this time, since the adhesion control layer 26 has not been patterned, the rear surface of the to-be-peeled layer 20 becomes flat as well. Subsequently, as in the above-described first embodiment, the TFT layer 30 and the display layer 40 are formed on the to-be-peeled layer 20, and subsequently, the to-be-peeled layer 20 is peeled off from the first substrate 22 by the transfer sheet 50. Finally, the TFT layer 30 and the display layer 40 are fixed onto the second substrate 11 together with the to-be-peeled layer 20, and thereby, the display unit 3 is completed. As described above, the separation section 24A and the adhesion section 24B may be formed by selective surface treatment of the adhesion control layer 26.

### APPLICATION EXAMPLES

The foregoing display unit 1 (and the display units 2 and 3) are applicable to a display unit of an electronic apparatus in any field for displaying an image signal inputted from outside or an image signal generated inside as an image or a video such as a television, a digital camera, a notebook personal computer, a portable terminal device such as a mobile phone, and a video camcorder.

### Application Example 1

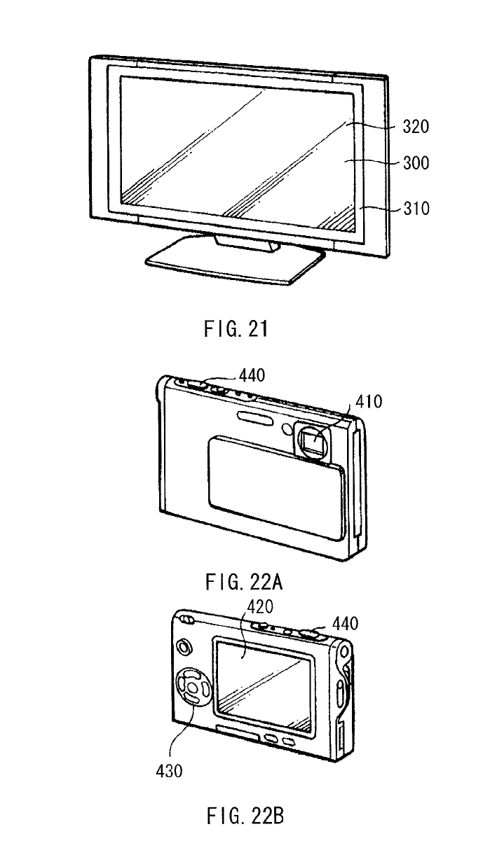

FIG. 21 illustrates an appearance of a television. The television may have, for example, an image display screen section 300 including a front panel 310 and a filter glass 320. The image display screen section 300 is configured of the foregoing display unit 1.

### Application Example 2

FIGS. 22A and 22B illustrate appearances of a digital still camera. The digital still camera may have, for example, a light emitting section 410 for a flash, a display section 420, a menu switch 430, and a shutter button 440. The display section 420 is configured of the foregoing display unit 1.

### Application Example 3

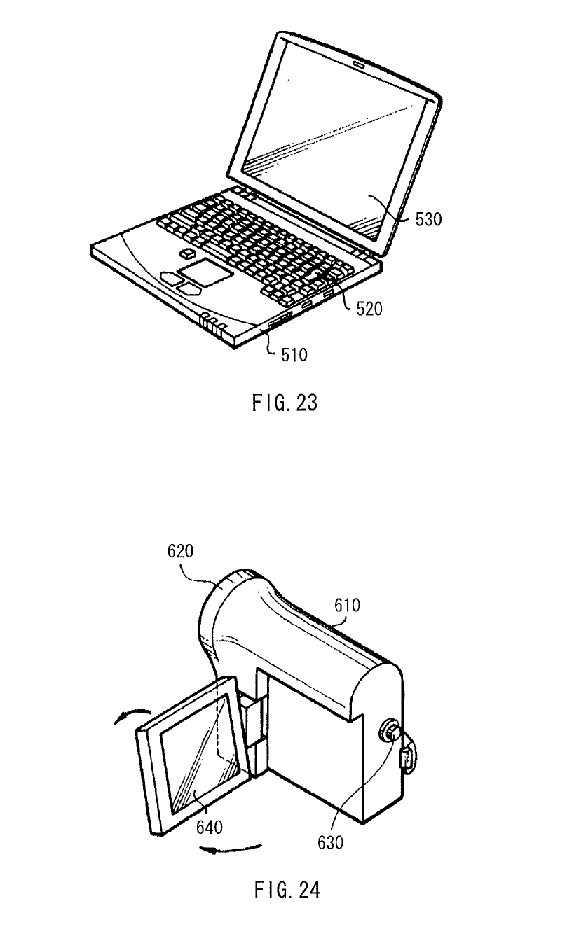

FIG. 23 illustrates an appearance of a notebook personal computer. The notebook personal computer may have, for example, a main body 510, a keyboard 520 for operation of inputting characters and the like, and a display section 530 for displaying an image. The display section 530 is configured of the foregoing display unit 1.

### Application Example 4

FIG. 24 illustrates an appearance of a video camcorder. The video camcorder may have, for example, a main body 610, a lens 620 for shooting a subject provided on the front side surface of the main body 610, a start-stop switch 630 for shooting, and a display section 640. The display section 640 is configured of the foregoing display unit 1.

### Application Example 5

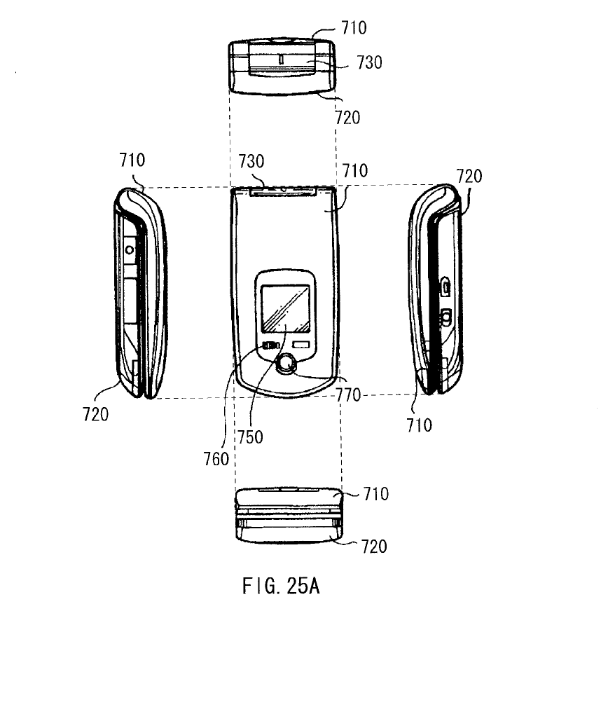

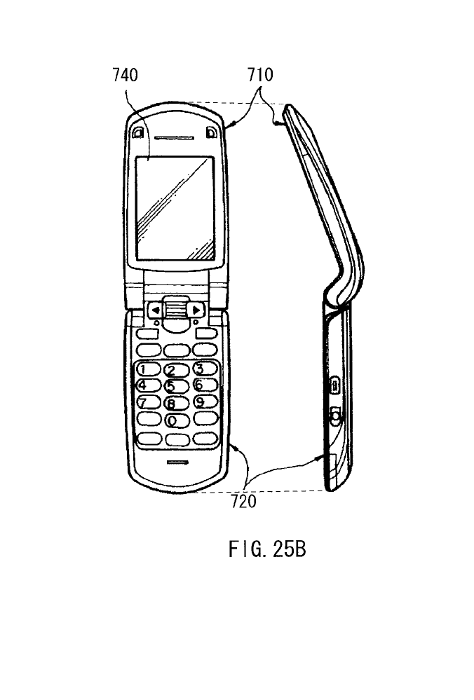

FIGS. 25A and 25B illustrate appearances of a mobile phone. In the mobile phone, for example, an upper package 710 and a lower package 720 may be jointed by a joint section (hinge section) 730. The mobile phone may have, for example, a display 740, a sub-display 750, a picture light 760, and a camera 770. The display 740 or the sub-display 750 is configured of the foregoing display unit 1.

While the present technology has been described with reference to the preferred embodiments and the modifications, the present technology is not limited to the foregoing embodiments and the like, and various modifications may be made. For example, in the foregoing embodiments and the like, the description has been given of the case that the semiconductor film 31 of the transistor 30T is made of polysilicon. Alternatively, the semiconductor film 31 may be made of other material such as oxide semiconductor and organic semiconductor. Further, in the foregoing embodiments and the like, the description has been given of the case that the display units 1, 2, and 3 have the TFT layer 30, that is, active-matrix-type display units. Alternatively, the display units 1, 2, and 3 may be passive-matrix-type display units.

Further, in the foregoing first embodiment and the foregoing second embodiment (display units 1 and 2), the case in which the front surface of the to-be-peeled layer 20 is sunk has been illustrated (FIG. 1 and FIG. 15). Alternatively, the front surface of the to-be-peeled layer 20 may be flat.

In addition thereto, in the foregoing third embodiment (display unit 3), the description has been given of the case that oxidation treatment by oxygen plasma is performed to form the separation section 24A and the adhesion section 24B in the adhesion control layer 26. Alternatively, the separation section 24A and the adhesion section 24B may be formed, for example, by ozone water treatment, UV ozone treatment, or the like.

Furthermore, the material, the thickness, the film-forming method, the film-forming conditions, and the like of each section are not limited to those described in the foregoing embodiments and the application examples thereof, and other material, other thickness, other film-forming method, and other film-forming conditions may be adopted.

In addition thereto, the display units according to the foregoing embodiments and the like are applicable to a display unit including an organic EL device, and are also applicable to display units including various display devices such as an inorganic EL device, a liquid crystal device, and an electrophoretic display device.

It is possible to achieve at least the following configurations from the above-described exemplary embodiments and the modifications of the disclosure.

(1) A method of manufacturing a multilayer film substrate, the method including:

forming an adhesion control layer on a first substrate, the adhesion control layer including an adhesion section and a separation section;

forming a to-be-peeled layer being fixed to the first substrate in the adhesion section and being inhibited from being adhered to the first substrate in the separation section;

laminating a function layer on the to-be-peeled layer;

peeling the function layer off from the first substrate together with the to-be-peeled layer; and

providing the function layer on a second substrate.

(2) The method of manufacturing the multilayer film substrate according to (1), wherein

the adhesion section and the separation section are formed by patterning the adhesion control layer, and

the to-be-peeled layer is in contact with the first substrate in the adhesion section.

(3) The method of manufacturing the multilayer film substrate according to (2), wherein a first close-contact layer fixing the adhesion control layer to the first substrate is provided between the adhesion control layer and the first substrate.

(4) The method of manufacturing the multilayer film substrate according to (2), wherein

a second close-contact layer fixing the adhesion control layer to the to-be-peeled layer is provided between the adhesion control layer and the to-be-peeled layer, and

the adhesion control layer is peeled off from the first substrate together with the to-be-peeled layer.

(5) The method of manufacturing the multilayer film substrate according to (1), wherein the adhesion control layer is configured of a first adhesion control layer and a second adhesion control layer, the first adhesion control layer including the separation section, and the second adhesion control layer including the adhesion section.

(6) The method of manufacturing the multilayer film substrate according to (5), wherein the second adhesion control layer is provided on part of a surface of the first adhesion control layer.

(7) The method of manufacturing the multilayer film substrate according to (6), wherein

a surface of the second adhesion control layer is covered with a third adhesion control layer including the separation section, and

the adhesion section is configured by exposing a side surface of the second adhesion control layer.

(8) The method of manufacturing the multilayer film substrate according to (1), wherein the adhesion control layer is selectively subjected to surface treatment, and thereby, the adhesion section and the separation section are formed.

(9) The method of manufacturing the multilayer film substrate according to (8), wherein oxidation treatment is performed as the surface treatment.

(10) The method of manufacturing the multilayer film substrate according to any one of (1) to (9), wherein the function layer and the to-be-peeled layer are physically peeled off from the first substrate.

(11) The method of manufacturing the multilayer film substrate according to any one of (1) to (10), wherein the first substrate having thickness that is larger than thickness of the second substrate is used.

(12) The method of manufacturing the multilayer film substrate according to any one of (1) to (11), wherein the second substrate is made of a flexible material.

(13) A method of manufacturing a semiconductor device, the method including:

forming an adhesion control layer on a first substrate, the adhesion control layer including an adhesion section and a separation section;

forming a to-be-peeled layer being fixed to the first substrate in the adhesion section and being inhibited from being adhered to the first substrate in the separation section;

laminating a semiconductor film on the to-be-peeled layer;

peeling the semiconductor film off from the first substrate together with the to-be-peeled layer; and

providing the semiconductor film on a second substrate.

(14) A method of manufacturing a display unit, the method including:

forming an adhesion control layer on a first substrate, the adhesion control layer including an adhesion section and a separation section;

forming a to-be-peeled layer being fixed to the first substrate in the adhesion section and being inhibited from being adhered to the first substrate in the separation section;

laminating a display layer on the to-be-peeled layer;

peeling the display layer off from the first substrate together with the to-be-peeled layer; and

providing the display layer on a second substrate.

(15) A method of manufacturing an electronic apparatus, the method including

forming a display unit, the forming the display unit including forming an adhesion control layer on a first substrate, the adhesion control layer including an adhesion section and a separation section,

forming an to-be-peeled layer being fixed to the first substrate in the adhesion section and being inhibited from being adhered to the first substrate in the separation section,

laminating a display layer on the to-be-peeled layer,

peeling the display layer off from the first substrate together with the to-be-peeled layer, and

providing the display layer on a second substrate.

(16) A multilayer film substrate including:

on a substrate,

a to-be-peeled layer including a concave section on a rear surface thereof; and

a function layer laminated on the to-be-peeled layer.

(17) The multilayer film substrate according to (16), wherein

the to-be-peeled layer includes a plurality of the concave sections, and

a front surface of the to-be-peeled layer is depressed between any two of the plurality of the concave sections adjacent to each other.

(18) The multilayer film substrate according to (16) or (17), wherein an adhesion control layer is included in the concave section, the adhesion control layer being fixed to the to-be-peeled layer.

(19) The multilayer film substrate according to any one of (16) to (18), wherein

the function layer is a display layer including a plurality of pixel regions, and

the pixel regions are each provided in a location that is opposed to the concave section of the to-be-peeled layer.

The present disclosure contains subject matter related to that disclosed in Japanese Priority Patent Application JP 2012-132947 filed in the Japan Patent Office on Jun. 12, 2012, the entire contents of which is hereby incorporated by reference.

It should be understood by those skilled in the art that various modifications, combinations, sub-combinations and alternations may occur depending on design requirements and other factors insofar as they are within the scope of the appended claims or the equivalents thereof.

What is claimed is:

1. A method of manufacturing a multilayer film substrate, the method comprising:
forming an adhesion control layer on a first substrate, the adhesion control layer including an adhesion section and a separation section;
forming a to-be-peeled layer being fixed to the first substrate in the adhesion section and being inhibited from being adhered to the first substrate in the separation section;
laminating a function layer on the to-be-peeled layer;
peeling the function layer off from the first substrate together with the to-be-peeled layer; and
providing the function layer on a second substrate.

2. The method of manufacturing the multilayer film substrate according to claim 1, wherein
the adhesion section and the separation section are formed by patterning the adhesion control layer, and
the to-be-peeled layer is in contact with the first substrate in the adhesion section.

3. The method of manufacturing the multilayer film substrate according to claim 2, wherein a first close-contact layer fixing the adhesion control layer to the first substrate is provided between the adhesion control layer and the first substrate.

4. The method of manufacturing the multilayer film substrate according to claim 2, wherein
a second close-contact layer fixing the adhesion control layer to the to-be-peeled layer is provided between the adhesion control layer and the to-be-peeled layer, and
the adhesion control layer is peeled off from the first substrate together with the to-be-peeled layer.

5. The method of manufacturing the multilayer film substrate according to claim 1, wherein the adhesion control layer is configured of a first adhesion control layer and a second adhesion control layer, the first adhesion control layer including the separation section, and the second adhesion control layer including the adhesion section.

6. The method of manufacturing the multilayer film substrate according to claim 5, wherein the second adhesion control layer is provided on part of a surface of the first adhesion control layer.

7. The method of manufacturing the multilayer film substrate according to claim 6, wherein
a surface of the second adhesion control layer is covered with a third adhesion control layer including the separation section, and
the adhesion section is configured by exposing a side surface of the second adhesion control layer.

8. The method of manufacturing the multilayer film substrate according to claim 1, wherein the adhesion control layer is selectively subjected to surface treatment, and thereby, the adhesion section and the separation section are formed.

9. The method of manufacturing the multilayer film substrate according to claim 8, wherein oxidation treatment is performed as the surface treatment.

10. The method of manufacturing the multilayer film substrate according to claim 1, wherein the function layer and the to-be-peeled layer are physically peeled off from the first substrate.

11. The method of manufacturing the multilayer film substrate according to claim 1, wherein the first substrate having thickness that is larger than thickness of the second substrate is used.

12. The method of manufacturing the multilayer film substrate according to claim 1, wherein the second substrate is made of a flexible material.

13. A method of manufacturing a semiconductor device, the method comprising:
forming an adhesion control layer on a first substrate, the adhesion control layer including an adhesion section and a separation section;
forming a to-be-peeled layer being fixed to the first substrate in the adhesion section and being inhibited from being adhered to the first substrate in the separation section;
laminating a semiconductor film on the to-be-peeled layer;
peeling the semiconductor film off from the first substrate together with the to-be-peeled layer; and
providing the semiconductor film on a second substrate.

14. A method of manufacturing a display unit, the method comprising:
forming an adhesion control layer on a first substrate, the adhesion control layer including an adhesion section and a separation section;
forming a to-be-peeled layer being fixed to the first substrate in the adhesion section and being inhibited from being adhered to the first substrate in the separation section;
laminating a display layer on the to-be-peeled layer;
peeling the display layer off from the first substrate together with the to-be-peeled layer; and
providing the display layer on a second substrate.

15. A method of manufacturing an electronic apparatus, the method comprising
forming a display unit, the forming the display unit including forming an adhesion control layer on a first substrate, the adhesion control layer including an adhesion section and a separation section,
forming an to-be-peeled layer being fixed to the first substrate in the adhesion section and being inhibited from being adhered to the first substrate in the separation section,
laminating a display layer on the to-be-peeled layer,
peeling the display layer off from the first substrate together with the to-be-peeled layer, and
providing the display layer on a second substrate.

16. A multilayer film substrate comprising:
on a substrate,
a to-be-peeled layer including a concave section on a rear surface thereof; and
a function layer laminated on the to-be-peeled layer.

17. The multilayer film substrate according to claim 16, wherein
the to-be-peeled layer includes a plurality of the concave sections, and
a front surface of the to-be-peeled layer is depressed between any two of the plurality of the concave sections adjacent to each other.

18. The multilayer film substrate according to claim 16, wherein an adhesion control layer is included in the concave section, the adhesion control layer being fixed to the to-be-peeled layer.

19. The multilayer film substrate according to claim 16, wherein
the function layer is a display layer including a plurality of pixel regions, and
the pixel regions are each provided in a location that is opposed to the concave section of the to-be-peeled layer.
